(19) United States
(12) Patent Application Publication
(10) Pub. No.: US 2017/0040300 A1
(43) Pub. Date: Feb. 9, 2017

(54) LIGHTING DEVICE AND METHOD FOR PRODUCING A LIGHTING DEVICE

(71) Applicant: PHILIPS LIGHTING HOLDING B.V., Eindhoven (NL)

(72) Inventors: Boudewijn Ruben DE JONG, EINDHOVEN (NL); Marc Andre DE SAMBER, EINDHOVEN (NL)

(21) Appl. No.: 15/124,370

(22) PCT Filed: Mar. 5, 2015
(86) PCT No.: PCT/EP2015/054605

§ 371 Date: Sep. 8, 2016

(30) Foreign Application Priority Data
Mar. 13, 2014 (EP) 14159554.6

(51) Int. Cl. H01L 25/075; H01L 33/56; H05K 3/02; H05K 1/18; H05K 3/04; H01L 33/62; H01L 25/16

(52) U.S. Cl. CPC H01L 25/0753; H01L 33/62; H01L 33/56; H01L 25/167; H05K 1/181; H05K 3/04; H05K 3/027; H01L 2933/0066; H01L 2933/005; H05K 2201/10106; H05K 2203/0228; H05K 2203/107

(57) ABSTRACT

A method for producing a lighting device is disclosed. The method comprises: providing two or more light sources (1, 9) sandwiched between and electrically connected to a first electrically conductive layer (5) and a second electrically conductive layer (7), the first electrically conductive layer (5) being transparent or translucent and both of the first (5) and second (7) electrically conductive layers initially lacking a conductive pattern; and thereafter forming a first electrically conductive pattern (16) in the first electrically conductive layer (5) and a second electrically conductive pattern (7) in the second electrically conductive layer (7) to provide at least one desired electrical circuit for the lighting device the first electrically conductive pattern (16) being different from the second electrically conductive pattern (17).

### FIELD OF THE INVENTION

The present disclosure relates to a lighting device and a method for producing a lighting device.

### BACKGROUND OF THE INVENTION

Many types of lighting devices are known and used in a variety of industrial, commercial and domestic applications. For large-area lighting, so-called light sheets are often practical. An illustrative example is the light sheet disclosed in US 2011/0180818. This light sheet is formed by light-emitting diodes (LEDs) embedded between two thin foils which support conductors connecting the LEDs.

Various methods for embedding and connecting LEDs and other types of solid-state lighting (SSL) devices between layers are known in the art. Since different applications impose different requirements on the shape of the lighting device, there is a need for methods that allow for the efficient production of lighting devices of various shapes. It is also desirable that electronic components for added functionality can be readily integrated into the lighting device during production. Known production methods can be improved in these respects.

US2010/0084665A1 discloses an electronically active sheet which includes a bottom substrate having a bottom electrically conductive surface. A top substrate having a top electrically conductive surface is disposed facing the bottom electrically conductive surface. An electrical insulator separates the bottom electrically conductive surface from the top electrically conductive surface. At least one bare die electronic element is provided having a top conductive side and a bottom conductive side. Each bare die electronic element is disposed so that the top conductive side is in electrical communication with the top electrically conductive surface and so that the bottom conductive side is in electrical communication with the bottom electrically conductive surface.

### SUMMARY OF THE INVENTION

A general objective of the present disclosure is to provide an improved or alternative method for producing a lighting device. Of particular interest are methods for embedding and interconnecting SSL devices and other types of electronic components between flexible layers.

The invention is defined by the independent claims. Embodiments are set forth in the dependent claims, the description and the drawings.

According to a first aspect, a method for producing a lighting device is provided. The method comprises providing two or more light sources sandwiched between and electrically connected to a first electrically conductive layer and a second electrically conductive layer, the first electrically conductive layer being transparent or translucent, and both of the first and second electrically conductive layers initially lacking a conductive pattern, and thereafter forming a first electrically conductive pattern in the first electrically conductive layer and a second electrically conductive pattern in the second electrically conductive layer to provide at least one desired electrical circuit for the lighting device, wherein the first electrically conductive pattern is different from the second electrically conductive pattern.

Forming the electrical circuitry of the lighting device at a late stage in the production process, i.e. after the two or more light sources are sandwiched between and electrically connected to the first electrically conductive layer and the second electrically conductive layer, may result in a more effective production process since fewer production steps need to be specifically adapted to the shape and the function of the end product. Different end products can be manufactured from a common assembly which initially lacks an electrical circuitry specific to a particular end product. This method may also facilitate the production of large-area lighting devices and the integration of electronic components for system intelligence into the lighting device.

The at least two light sources can be SSL devices, for example semiconductor LEDs, organic LEDs, polymer LEDs or laser diodes. The light sources can be of different kinds. SSL devices are energy efficient and have a long life time. They can be particularly suitable for lighting devices having embedded light sources.

The second electrically conductive layer can be transparent or translucent. The lighting device can thus easily be adapted to emit light through both the first and the second electrically conductive layers, something which can be advantageous in some applications.

The first and second electrically conductive layers can be flexible, for example flexible foils. The first electrically conductive layer can be provided on a first substrate, and the second electrically conductive layer can be provided on a second substrate. The first and second substrates can be flexible. By the use of flexible conductive layers and substrates, the method may allow for the production of lighting devices for use on curved surfaces. Moreover, it may be possible to arrange the lighting device on a curved surface already during production and to use roll-to-roll production.

The at least one desired electrical circuit formed by the first and second electrically conductive patterns can be a series circuit or a parallel circuit or a combination thereof.

The first and second conductive patterns can be formed by cutting through, and hence forming trenches through, the first and second electrically conductive layers, for example by laser cutting or mechanical cutting. The first and second substrates can be cut in accordance with the first and second electrically conductive patterns by providing trenches in the first and second electrically conductive layers that are cut through the conductive part of the electrically conductive layers and trenches in the respective substrates that are cut partly in, and not through, the respective substrates.

The step of providing said assembly can comprise: arranging at least one light source of the two or more light sources on the first electrically conductive layer; arranging at least one light source of the two or more light sources on the second electrically conductive layer, and bringing the first and second electrically conductive layers together, thereby sandwiching the at least one light source arranged on the first electrically conductive layer and the at least one light source arranged on the second electrically conductive layer between the first and second electrically conductive layers.

The step of providing said assembly can comprise: arranging the two or more light sources on one of the first and second electrically conductive layers, and applying the other one of the first and second electrically conductive layers over the two or more light sources, thereby sandwiching the two or more light sources between the first and second electrically conductive layers.

The two or more light sources can form a pattern having a repeating unit which comprises at least two light sources. The two or more light sources can be oriented in opposite directions such that, in operation, a first light source emits light in a direction opposite to that of a second light source.

The method can comprise a step of providing two or more additional electronic components sandwiched between and electrically connected to the first and second electrically conductive layers. The two or more light sources and the two or more electronic components can form a pattern having a repeating unit which comprises at least one of the two or more light sources and at least one of the two or more electronic components.

The method can comprise a step of arranging a fill material between the first and second electrically conductive layers. The fill material can be pre-formed based on positions and sizes of the two or more light sources. The fill material can be optically active, and it can be a hot-melt material or a shape-memory polymer.

The method can comprise a step of arranging one or more protective coatings on the outside of at least one of the first and second substrates. The one or more protective coatings can be arranged so as to fill voids formed when cutting the first and second electrically conductive layers and the first and second substrates in order to provide an electrically isolating coating that protects regions exposed in the voids or trenches. The method can comprise a step of arranging one or more optically active coatings on at least one of the one or more protective coatings.

The method can comprise a step of removing a contour portion of the lighting device, which contour portion does not contain the at least one desired electrical circuit.

The method can comprise a step of forming the lighting device under production into a desired three-dimensional shape, for example by vacuum forming or thermoforming.

According to a second aspect, a lighting device is provided. The lighting device according to the second aspect comprises: a first substrate, a first electrically conductive layer provided on top of the first substrate, at least two light sources provided on top of and electrically connected to the first electrically conductive layer, a second electrically conductive layer provided on top of and electrically connected to the at least two light sources, and a second substrate provided on top of the second electrically conductive layer. The first substrate and the first electrically conductive layer comprise trenches that form a first electrically conductive pattern in the first electrically conductive layer, and the second substrate and the second electrically conductive layer comprise trenches that form a second electrically conductive pattern in the second electrically conductive layer, the first and second electrically conductive patterns being different and providing at least one desired electrical circuit for the lighting device. A cutting process provides that trenches are formed in the first substrate and the first electrically conductive layer and in the second substrate and the second electrically conductive layer. These trenches cut through the conductive parts of the first and second electrically conductive layers such that a desired electrical circuit is provided, and the trenches cut partly into the first and second substrates.

This aspect may exhibit the same or similar features and technical effects as the first aspect of the invention.

In an embodiment the at least two light sources in operation emit light in opposite directions. This provides for a lighting device which may emit light in opposite directions.

It is noted that the invention relates to all possible combinations of features recited in the claims.

### BRIEF DESCRIPTION OF THE DRAWINGS

These and other aspects of the present invention will now be described in more detail, with reference to the appended drawings showing embodiment(s) of the invention.

FIGS. 1l-1f are schematic side views of a lighting device under production.

FIGS. 2a-2b are schematic top views of two variants of the lighting device under production in FIG. 1e or 1f.

FIG. 3 illustrates schematically a perspective and partially cut view of a lighting device.

As illustrated in the figures, the sizes of layers and regions are exaggerated for illustrative purposes and, thus, are provided to illustrate the general structures of embodiments of the present invention. Like reference numerals refer to like elements throughout.

### DETAILED DESCRIPTION

The present invention will now be described more fully hereinafter with reference to the accompanying drawings, in which currently preferred embodiments of the invention are shown. This invention may, however, be embodied in many different forms and should not be construed as limited to the embodiments set forth herein; rather, these embodiments are provided for thoroughness and completeness, and fully convey the scope of the invention to the skilled person.

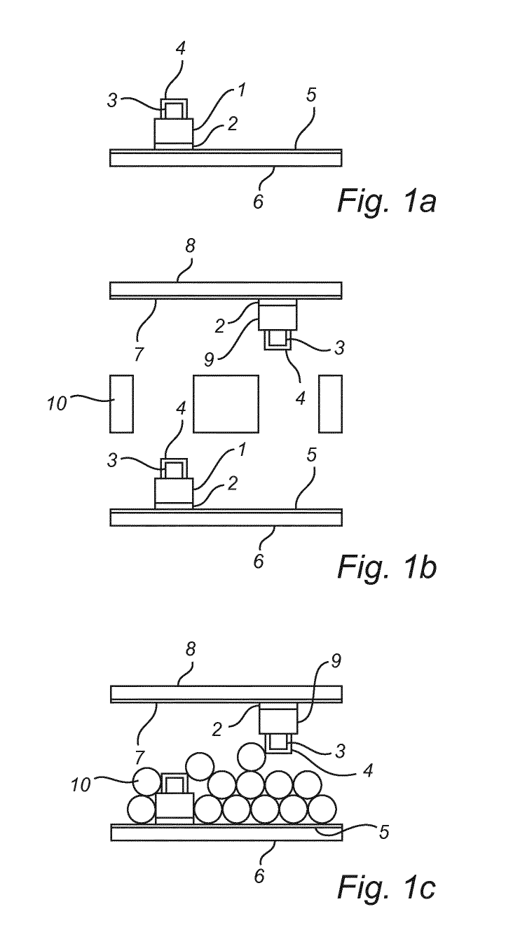

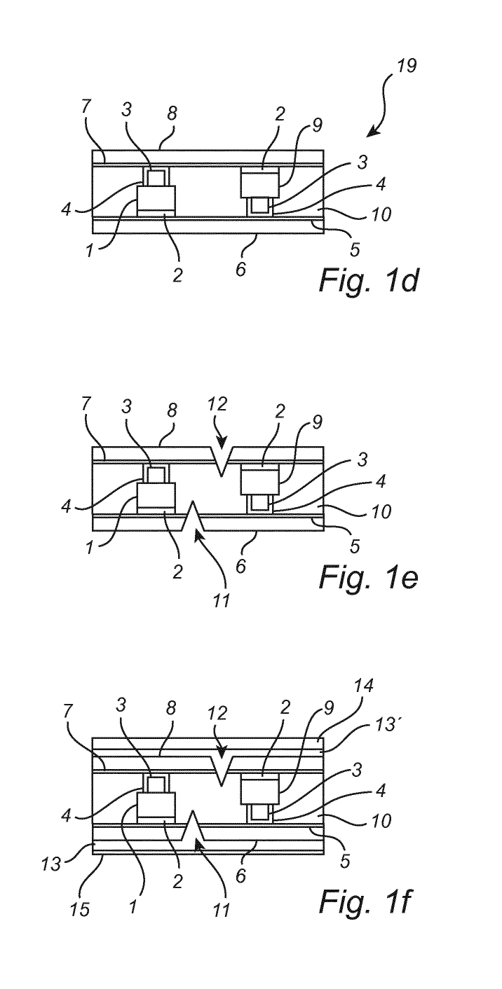

A method for producing a lighting device will be described with reference to the FIGS. 1a to 1f. As is exemplified in FIG. 1a, an initial step consists of arranging several electronic components 1 on a first electrically conductive layer 5 so that the electronic components 1 are attached to as well as electrically connected to the first electrically conductive layer 5. The total number of electronic components 1 on the first conductive layer 5 depends for example on the size of lighting device to be produced and its intended application. For clarity, only one electronic component 1 is shown in FIG. 1a. There is at least one light source among the electronic components 1. The electronic components 1 can also include for example one or more jumpers, zero-ohm components, rectifiers and/or discrete semiconductor components such as Si diodes. The electronic component 1 in FIG. 1a is an LED, and, for simplicity, the electronic components 1 will henceforth be referred to as the bottom LEDs. The first electrically conductive layer 5 will, for brevity, be referred to as the bottom layer 5.

The bottom layer 5 in FIG. 1a lacks a conductive pattern. In other words, it is ‘unstructured’ and comprises a continuous conductive layer. Further, the bottom layer 5 is transparent or translucent. It can be a foil or a film of one or more transparent, or translucent, and conductive materials, for example indium tin oxide or indium zinc oxide. The bottom layer 5 can be formed by one or more hybrid materials, such as indium tin oxide with added conductors (for example silver needles, carbon nanotube needles, graphene flakes or any type of conducting fibers, flakes or particles) or a transparent material similar to an isotropic conductive adhesive (for example a material based on a transparent silicone matrix with flakes of a transparent and conducting material). The bottom layer 5 can be arranged on a transparent, or translucent, bottom substrate 6. The bottom layer 5 and the bottom substrate 6 can be flexible. The shape of the bottom layer 5 and the bottom substrate 6 is typically rectangular, although other shapes are conceivable. The substrate 6 is typically made of plastic material, such as polyurethane, polyethylene terephthalate or polyethylene naphthalate. The substrate 6 can be made of silicone.

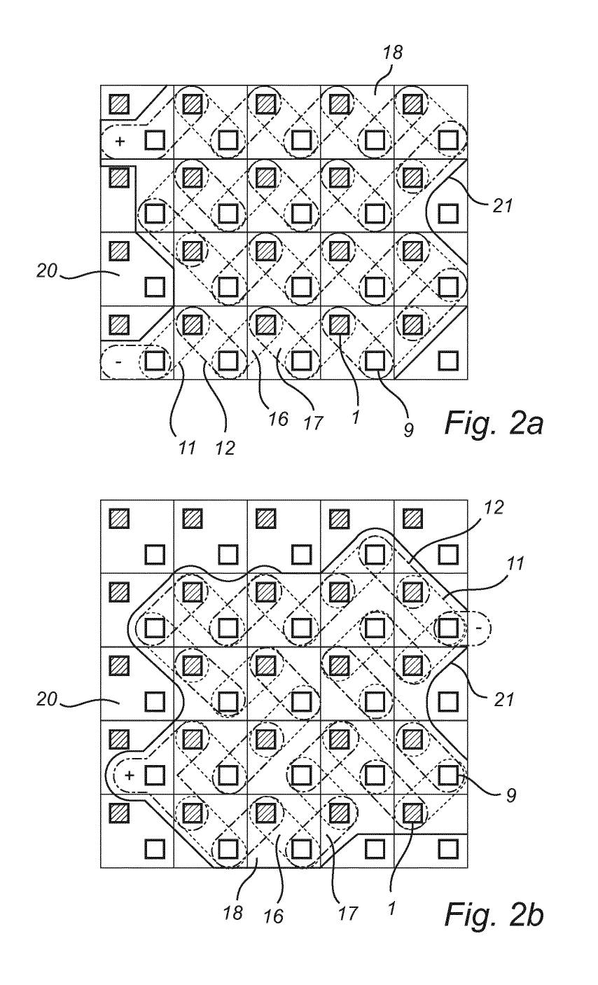

A pick-and-place machine can be used to place the bottom LEDs 1 on the bottom layer 5. The bottom LEDs 1 can be attached to the bottom layer 5 by means of attachments 2, for example formed by a die attach film or some other adhesive conductor. Each of the bottom LEDs 1 can be provided with an abutment 3 which may have an adhesive and conductive coating 4, for example stud bumps on which an isotropic conductive adhesive, such as a silver-filled epoxy glue, has been roller coated. As will be further discussed in connection with FIGS. 2a and 2b, the bottom LEDs 1 are typically arranged on the bottom layer 5 in a pattern having a repeating unit.

FIGS. 1b and 1c show a step of forming an assembly 19, specifically a laminate, comprising the bottom layer 5, the bottom LEDs 1 and several electronic components 9 that are electrically connected to a second electrically conductive layer 7. For clarity, only one electronic component 9 is shown in FIG. 1b. The electronic components 9 include at least one light source and can also include, for example, jumpers, zero-ohm components, rectifiers and/or discrete semiconductor components such as Si diodes. The electronic component 9 in FIG. 1b is an LED, and the electronic components 9 will be referred to as the top LEDs. The second electrically conductive layer 7 will be referred to as the top layer.

The top layer 7 is typically similar to the bottom layer 5. Namely, the top layer of FIGS. 1b and 1c also lacks a conductive pattern. In other words, it is ‘unstructured’ and comprises a continuous conductive layer. The top layer 7, however, can be translucent, transparent or non-transparent, depending on the desired direction of illumination of the lighting device under production. The top layer 7 can for example be a foil or a film of indium tin oxide or indium zinc oxide. The top layer 7 can be formed by a hybrid material, such as indium tin oxide with added conductors (for example silver needles, carbon nanotube needles, graphene flakes or any type of conducting fibers, flakes or particles) or a transparent material similar to an isotropic conductive adhesive (for example a material based on a transparent silicone matrix with flakes of a transparent and conducting material). The top layer 7 can be arranged on a top substrate 8 which can be translucent, transparent or non-transparent. The top layer 7 and the top substrate 8 can be flexible. The shape of the top layer 7 and the top substrate 8 is typically the same as that of the bottom layer 5.

The top LEDs 9 can be similar to the bottom LEDs 1. That is to say, the top LEDs 9 can be attached to the top layer 7 by means of attachments 2, formed by for example a die attach film or some other adhesive conductor, and they can be provided with abutments 3 which may have an adhesive and conductive coating 4, for example stud bumps on which an isotropic conductive adhesive has been roller coated. The top LEDs 9 are typically arranged on the top layer 7 according to a pattern which corresponds to the pattern of the bottom LEDs 1 on the bottom substrate 5. The top LEDs 9 and the bottom LEDs 1 are thus typically sandwiched in an opposite orientation. In an embodiment both the top LED 9 and bottom LED 1 may, in operation emit light wherein a light emitting direction of the top LED 9 is opposite to a light emitting direction of the bottom LED 1 thereby providing for a lighting device which may emit light in two opposite directions.

A solid structure can be obtained by arranging a fill material 10 between the top layer 7 and the bottom layer 5. The fill material 10 can be transparent or translucent, and it can be a hot-melt material, a stretchable material or a shape-memory polymer. The fill material 10 can for example be silicone, ethylene vinyl acetate, polyurethane, thermoplastic polyurethane or Desmopan® from Bayer MaterialScience. The fill material 10 can be optically active, and it can, for example, be adapted to deflect light. The fill material 10 may comprise a host material to which light-diffusion particles having a different refractive index than the host material have been added. Typical examples of such particles are silver particles and titanium dioxide particles. The fill material 10 may comprise a host material and light-conversion particles, such as phosphor particles, added to the host material.

As is shown in FIG. 1c, the fill material 10 may comprise micro-spheres arranged on the bottom layer 5 or the top layer 7 prior to lamination. Alternatively, the fill material 10 may comprise a sheet which is pre-formed based on the positions and sizes of the top 9 and bottom 1 LEDs, i.e. a sheet with holes for receiving the top 9 and bottom 1 LEDs. A fill material 10 in the form of a pre-formed sheet is shown in FIG. 1b. Such a sheet can be arranged on the top layer 7 or the bottom layer 5 prior to or during lamination.

The assembly or laminate 19 is formed by bringing the top 7 and bottom 5 layers together so as to sandwich the top 9 and bottom 1 LEDs between the top 7 and bottom 5 layers, see FIG. 1d. Standard lamination techniques, such as a vacuum lamination technique, can be used. If the fill material 10 is a hot-melt material, the lamination process typically includes a heating step in which the fill material 10 is melted, the melt filling voids and cavities between the top 7 and bottom 5 layers. After lamination, the top 9 and bottom 1 LEDs are embedded between the top 7 and bottom 5 layers and electrically connected to both the top layer 7 and the bottom layer 5. The top 9 and bottom 1 LEDs can be in ohmic contact with the top 7 and bottom 5 layers so that a current can flow in both directions through the top 9 and bottom 1 LEDs.

After lamination, a first electrically conductive pattern is formed in the bottom layer 5 and a second electrically conductive pattern is formed in the top layer 7 by a patterning process, whereby a desired electrical circuit, which connects the top 9 and bottom 1 LEDs, is formed. In other words, the layers 5 and 7 now become ‘structured’ and the conductive layer is not a continuous conductive layer anymore. The first and second electrically conductive patterns are further discussed in connection with FIGS. 2a and 2b. The patterning process typically includes forming bottom cuts or trenches 11 and top cuts or trenches 12 in the bottom layer 5 and top layer 7, respectively, for example by laser cutting or mechanical cutting. The top 12 and bottom 11 cuts or trenches are illustrated in FIG. 1e which also shows cuts or trenches formed in the top 8 and bottom 6 substrates as a result of the patterning process. As shown in FIG. 1e, the cuts or trenches formed in the top 8 and bottom 6 substrates only cut partly in, and not through, the respective substrates.

Additional layers can be applied to the patterned top 5 and bottom 7 layers. Examples of such additional layers are shown in FIG. 1f. For instance, a bottom protective coating 13 and a top protective coating 13′ can be applied to the patterned top 7 layer and/or the patterned bottom 5 layer, respectively, in order to fill the voids formed by the bottom 11 and top 12 cuts. This may also provide for an electrical isolation of regions exposed in the voids. The top protective coating 13′ and/or the bottom protective coating 13 can provide a sticking surface, and at least one of them is transparent or translucent. One or both of the top 13′ and bottom 13 protective coatings can be optically active coatings. They can be adapted to diffuse light or re-direct light, for instance. The top 13′ and bottom 13 protective coatings can be color converting. The light-converting capabilities of the top 13′ and bottom 13 protective coatings can be different, for example, they can be adapted to convert light into different colors. The top 13′ and bottom 13 protective coatings may comprise silicone or polyurethane, for instance.

One or more optically active coatings 14 can be applied to one or both of the top 13′ and bottom 13 protective coatings. Examples of optically active coatings 14 are color converting coatings, light diffusing coatings and light re-directing coatings. The optically active coating may comprise phosphor, titanium dioxide and/or glass spheres. In FIG. 1f, the top protective coating 13′ is provided with an optically active coating 14. The bottom protective coating 13 is, on the other hand, provided with a reflector 15, such as a silver layer, an aluminum layer or a silicone layer with titanium dioxide particles. The reflector 15 may comprise a MIRO® surface or a MIRO-SILVER® surface from Alanod. The reflector 15 can be a dichroic filter reflecting only certain wavelengths. This construction provides light emitted by the top 9 and bottom 1 LEDs to exit through the top layer 7. Light striking the reflector 15 is reflected towards the top layer 7. The general direction of illumination of a lighting device produced according to the arrangement in FIG. 1f is thus upwards. The reflector 15 can of course be omitted. In such an embodiment, light can exit through the top layer 7 as well as through the bottom layer 5 so that the lighting device provides illumination both upwards and downwards.

FIGS. 2a and 2b show schematic top views of two variants of the lighting device in FIG. 1e or 1f. As is illustrated in FIGS. 2a and 2b, the top cuts or trenches 12 are identified by the dash dot lines define top sections 17 in the top layer 7, and the bottom cuts or trenches 11 are identified by the dash lines define bottom sections 16 in the bottom layer 5. The bottom sections 16 and top sections 17 form a first electrically conductive pattern and a second electrically conductive pattern, respectively, thereby electrically interconnecting the top 9 and bottom 1 LEDs so that a desired electrical circuit for the lighting device under production is formed. In FIG. 2a, the top 9 and bottom 1 LEDs are connected in series between a positive end and a negative end. An example of a series-parallel connection of the top 9 and bottom 1 LEDs is shown in FIG. 2b. Of course, many other types of connections are conceivable. As shown in FIGS. 2a and 2b the first electrically conductive pattern is different from the second electrically conductive pattern which is achieved by providing the top cuts or trenches 12 according to a pattern which is different from that of the bottom cuts or trenches 11.

As is shown in FIGS. 2a and 2b, the top 9 and bottom 1 LEDs form a pattern which defines a repeating unit 18. The repeating unit 18 in FIGS. 2a and 2b is square and comprises one bottom LED 1 and one top LED 9 which are oriented in different directions. The LEDs 1 and 9 may for example be oriented in opposite directions. It should be noted that the repeating unit 18 can have any shape, for example that of a rectangle, a parallelogram or a triangle, and may comprise, in addition to at least one light source, one or more electronic components which are not light sources, such as jumpers, zero-ohm components, rectifiers and discrete semiconductor components such as Si diodes. Furthermore, the repeating unit 18 may comprise more than two light sources, and the light sources can be oriented in the same direction.

The lighting device can further be formed, for example by removing one or more contour portions 20 which do not contain the desired electrical circuit. The one or more contour portions 20 can be removed by cutting along a desired free-form contour 21, as indicated by bold solid lines in FIGS. 2a and 2b. Laser cutting and/or mechanical cutting can for example be used to cut through the various layers, substrates and coatings described above. The free-form contour 21 will define the circumferential edge of the finalized lighting device, and it encloses the top 12 and bottom 11 cuts without crossing them. The free-form contour 21 can be curved or straight. The free-form contour 21 can have curved portions and straight portions, and it can be symmetric or asymmetric.

Additional steps are typically performed in order to finalize the lighting device under production, such as a step of sealing the circumferential edge after removal of the contour portions 20. There may be a step in which the lighting device under production is formed into a desired three-dimensional shape, for example by heating it into a moldable shape and stretching it over a mold.

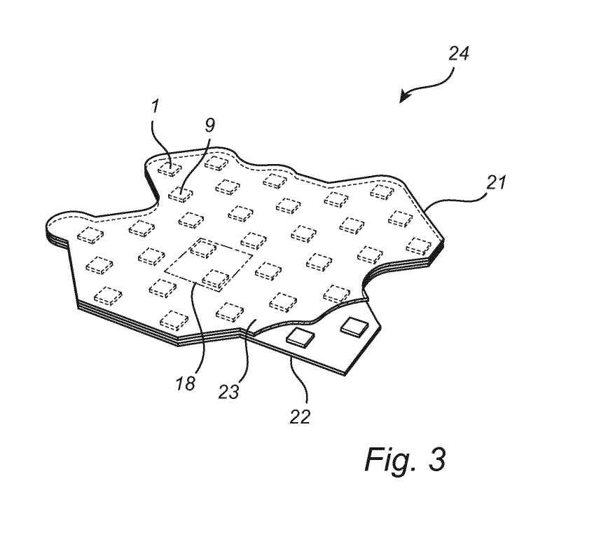

FIG. 3 shows a perspective and schematic view of a lighting device 24 having a planar shape defined by the free-form contour 21 which has straight portions and curved portions. The lighting device 24 comprises a top sheet 23 and a bottom sheet 22, at least one of which is transparent or translucent. The top 23 and bottom 22 sheets may be flexible, and each sheet comprises an electrically conductive layer which may be arranged on a substrate. The substrates can for example be made of polyurethane, polyethylene terephthalate, polyethylene naphthalate or silicone. Examples of electrically conductive layers are indium tin oxide foils, indium zinc oxide foils. Other examples are foils of a hybrid material such as indium tin oxide with added conductors (for example silver needles, carbon nanotube needles, graphene flakes or any type of conducting fibers, flakes or particles) and a foil of a transparent material similar to an isotropic conductive adhesive (for example a material based on a transparent silicone matrix with flakes of a transparent and conducting material). The top 23 and bottom 22 sheets may comprise one or more optically active layers, such as light-diffusing layers, light-redirecting layers and/or color-converting layers. Furthermore, a fill material is typically arranged between the top 23 and bottom 22 sheets in order to fill the space between them. The fill material can be a hot-melt material, a stretchable material or a shape-memory polymer, for instance.

The lighting device 24 in FIG. 3 has light sources in the form of top LEDs 9 and bottom LEDs 1 which are sandwiched between the top sheet 23 and bottom sheet 22 and arranged in a pattern forming a repeating unit 18. In FIG. 3, the repeating unit 18 is rectangular and comprises one top LED 9 and one bottom LED 1. It should be noted that, in general, the repeating unit 18 may have any shape and may comprise more than two light sources. It should also be noted that the lighting device 24 may comprise additional electronic components which are electrically connected to the light sources and form part of the repeating unit 18. Examples of such electronic components are jumpers, zero-ohm components, rectifiers and discrete semiconductor components such as Si diodes. The lighting device 24 can be produced according the method described in connection with the FIGS. 1l-1f and 2a-2b.

The lighting device 24 is put in operation by connecting it to a power source. The top LEDs 9 and bottom LEDs 1 emit light through the bottom sheet 22 and/or the top sheet 23, depending on whether both sheets are transparent or translucent, or if only one of them is transparent or translucent. Hence, the direction of illumination of the lighting device 24 can be through the bottom sheet 22, the top sheet 23 or through both the top sheet 23 and bottom sheet 22.

The person skilled in the art realizes that the present invention by no means is limited to the preferred embodiments described above. On the contrary, many modifications and variations are possible within the scope of the appended claims. For example, instead of arranging the light sources on both the first and second electrically conductive layers prior to sandwiching the light sources between these layers, all of the light sources can be arranged on either the first electrically conductive layer or the second electrically conductive layer. Furthermore, the light sources can be arranged in a pattern forming a sign, such as a letter.

Additionally, variations to the disclosed embodiments can be understood and effected by the skilled person in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measured cannot be used to advantage.

1. Method for producing a lighting device, the method comprising:
providing an assembly which includes two or more light sources sandwiched between and electrically connected to a first electrically conductive layer and a second electrically conductive layer, the first electrically conductive layer being transparent or translucent and both of the first and second electrically conductive layers initially lacking a conductive pattern, and the first electrically conductive layer being provided on a first substrate, and the second electrically conductive layer being provided on a second substrate; and
thereafter forming a first electrically conductive pattern in the first electrically conductive layer and a second electrically conductive pattern in the second electrically conductive layer to provide at least one desired electrical circuit for the lighting device, the first electrically conductive pattern being different from the second electrically conductive pattern,
wherein the first and second conductive patterns are formed by forming trenches through the first and second electrically conductive layers, wherein the trenches are also formed in the first and second substrates in accordance with the first and second electrically conductive patterns.

2. The method according to claim 1, wherein the at least two light sources are solid-state lighting devices.

3. The method according to claim 1, wherein the second electrically conductive layer is transparent or translucent.

4. The method according to claim 1, wherein the first and second substrates are flexible.

5. The method according to claim 1, wherein the at least one desired electrical circuit formed by the first and second electrically conductive patterns is a series circuit or a parallel circuit or a combination thereof.

6. The method according to claim 1, wherein the two or more light sources form a pattern having a repeating unit, the repeating unit comprising at least two light sources, at least two of which are oriented in opposite directions.

7. The method according to claim 1, further comprising providing two or more additional electronic components sandwiched between and electrically connected to the first and second electrically conductive layers.

8. The method according to claim 7, wherein the two or more light sources and the two or more electronic components form a pattern having a repeating unit, the repeating unit comprising at least one of the two or more light sources and at least one of the two or more electronic components.

9. The method according to claim 1, further comprising arranging a fill material between the first and second electrically conductive layers.

10. The method according to claim 1, further comprising arranging one or more protective coatings on the outside of at least one of the first and second substrates.

11. The method according to claim 1, wherein the one or more protective coatings fill the trenches formed in the first and second electrically conductive layers and the first and second substrates.

12. A lighting device, comprising:
a first substrate;
a first electrically conductive layer provided on top of the first substrate;
at least two light sources provided on top of and electrically connected to the first electrically conductive layer;
a second electrically conductive layer provided on top of and electrically connected to the at least two light sources; and
a second substrate provided on top of the second electrically conductive layer,
wherein the first substrate and the first electrically conductive layer comprise trenches that form a first electrically conductive pattern in the first electrically conductive layer, and the second substrate and the second electrically conductive layer comprise trenches that form a second electrically conductive pattern in the second electrically conductive layer, the first and second electrically conductive patterns being different and providing at least one desired electrical circuit of the lighting device.

13. The lighting device according to claim 13, wherein the at least two light sources in operation emit light in opposite directions.

14. The lighting device according to claim 13, wherein the at least two light sources are solid-state lighting devices.

15. The lighting device according to claim 13, wherein the second electrically conductive layer is transparent or translucent.
